(19) United States
(12) Patent Application Publication
(10) Pub. No.: US 2018/0252859 A1
(43) Pub. Date: Sep. 6, 2018

(54) LIGHTING DEVICE AND DISPLAY DEVICE

(71) Applicant: SHARP KABUSHIKI KAISHA, Sakai City, Osaka (JP)

(72) Inventor: YUUSUKE YAMAMOTO, Sakai City (JP)

(21) Appl. No.: 15/755,555

(22) PCT Filed: Aug. 26, 2016
(86) PCT No.: PCT/JP2016/074923

§ 371 Date: Feb. 27, 2018

(30) Foreign Application Priority Data
Aug. 31, 2015 (JP) 2015-170748

(51) Int. Cl. F21V 8/00; H05K 1/03; H05K 1/18

(52) U.S. Cl. CPC G02B 6/0083; H05K 1/0393; H05K 2201/10136; G02B 6/0073; H05K 2201/10106; H05K 1/181

(57) ABSTRACT

A backlight device 20 includes LEDs 21, a metal housing 40 that accommodates the LEDs 21, an LED drive substrate 26 that is disposed outside the housing 40 and drives the LEDs 21, and an LED-mounted substrate 30 on which the LEDs 21 are mounted. The LED-mounted substrate 30 includes a connector portion 31 disposed outside the housing 40 and connected to the LED drive substrate 26, a wiring pattern 32 that connects the connector portion 31 and the LEDs 21, and a conductive layer 33 that is exposed on a substrate surface 30B facing the housing 40 at a position overlapping the wiring pattern 32 and is conductive but electrically independent of the wiring pattern 32. A display device of this embodiment includes the backlight device 20 described above, and a liquid crystal panel 11 that uses light from the backlight device 20 for display purposes.

### TECHNICAL FIELD

The present invention relates to a lighting device and a display device.

### BACKGROUND ART

As one example of a liquid crystal display device equipped with a lighting device, one that is described in Patent Document 1 specified below is known. Patent Document 1 discloses provision of a discharge path as a countermeasure for ESD (electrostatic discharge) by forming a conductor portion such as a shield layer in flexible substrates and control substrates disposed outside the backlight unit (lighting device) of the liquid crystal display device. Such a configuration allegedly allows ESD-induced charges to be released to the outside via the shield layer or the like.

### CITATION LIST

### Patent Document

Patent Document 1: Japanese Patent Application Laid-Open No. 2014-123640

### Problem to be Solved by the Invention

With the configuration disclosed in Patent Document 1, however, it has been sometimes hard to provide the ESD countermeasure due to design limitations of the liquid crystal display device (e.g. structural limitations such as a difficulty in electrically connecting a control substrate and a metal frame depending on the arrangement of the control substrate).

With the demands for size reduction of lighting devices in recent years, it has been also difficult to provide ESD countermeasures in a limited space inside the housing of a lighting device such as a metal frame. In a configuration, in particular, in which a connector portion of a light source-mounted substrate on which a light source is mounted inside the housing is extended out of the housing for connection with a light source drive substrate outside the housing, there is no space provided for forming the connector portion inside the housing due to the need to reduce the size of the lighting device. It has been difficult to provide an ESD countermeasure in such a very confined space allotted to the light source-mounted substrate without increasing such a space.

### DISCLOSURE OF THE PRESENT INVENTION

The present invention has been completed based on the circumstances described above and it is an object of the invention to provide a favorable ESD countermeasure in a confined space inside a housing to protect the lighting device and light sources from ESD.

### Means for Solving the Problem

A lighting device according to the present invention includes: a light source; a metal housing that accommodates the light source; a light source drive substrate that is disposed outside the housing and drives the light source; and a light source-mounted substrate on which the light source is mounted. The light source-mounted substrate includes a connector portion disposed outside the housing and connected to the light source drive substrate, a wiring pattern that connects the connector portion and the light source, and a conductive layer that is exposed on a substrate surface facing the housing at a position overlapping the wiring pattern and is conductive but electrically independent of the wiring pattern.

For the light source-mounted substrate that is disposed in a confined space inside a housing, the present invention utilizes the structure in which the light source-mounted substrate and housing are disposed in close proximity to each other, to make the housing and a conductive layer exposed on the opposite substrate surface conductive to each other. This conductive layer is provided as a laminar member at a position overlapping the wiring pattern on the light source-mounted substrate so that it can be formed inside the housing without significantly extending the space for placing the light source-mounted substrate, as compared to when disposing an additional component separate from the light source-mounted substrate inside the housing, or when securing an area for forming the conductive layer in such a manner that the substrate surface area of the light source-mounted substrate is increased. Thus, the low-impedance conductive layer can be formed favorably even in a confined space inside the housing to release ESD current to the housing via the conductive layer. As a result, ESD-induced malfunctions of the lighting device and destruction of circuit components such as light sources can be prevented favorably.

In the configuration described above, the light source-mounted substrate may have the light source mounted on one substrate surface and the conductive layer formed on the other substrate surface, and may be disposed such that the other substrate surface faces an inner face of the housing. Such a configuration is favorable because when the light source-mounted substrate is accommodated inside the housing, the conductive layer can be positioned opposite the housing.

In the configuration described above, the housing may include a protruded portion provided on the inner face, and the light source-mounted substrate may have the conductive layer formed at a position facing the protruded portion. In such a configuration, as compared to one without the protruded portion, the distance between the conductive layer and the inner face of the housing can be made smaller, which allows favorable release of electric current from the conductive layer to the housing.

In the configuration described above, the light source-mounted substrate is a flexible substrate having flexibility, and has the conductive layer formed at its peripheral end. The peripheral end may be resiliently deformed in such a way as to ride onto the protruded portion so that the conductive layer in contact with the protruded portion is biased toward the protruded portion. in such a configuration, the conductive layer and protruded portion can favorably be contacted to each other, which allows favorable release of electric current from the conductive layer to the housing.

In the configuration described above, the light source-mounted substrate may be fixed to the housing at a position in close proximity to the conductive layer. In such a configuration, the conductive layer can be prevented from displacing away from the housing, which allows favorable release of electric current from the conductive layer to the housing.

in the configuration described above, the housing may include a bottom plate, a side plate extending upright from a peripheral end of the bottom plate, and a through hole extending through the side plate. The light source-mounted substrate may be disposed on an inner side of the side plate, while the connector portion may be extended out of the housing through the through hole. In such a configuration, the space for placing the light source-mounted substrate inside the housing can favorably be made small, which contributes to size reduction of the lighting device.

in the configuration described above, the housing may include a plate portion for disposing the light source-mounted substrate on an inner side thereof, and a cantilever portion cut away from the plate portion in a cantilevered manner and sandwiching the light source-mounted substrate between itself and the plate portion. The light source-mounted substrate may have the conductive layer at a position facing the cantilever portion. In such a configuration, the conductive layer and cantilever portion can readily be contacted to each other, which allows favorable release of electric current from the conductive layer to the housing.

In the configuration described above, the light source-mounted substrate may be a flexible substrate having flexibility. A Flexible substrate generally has a small thickness and can readily be bent in part to be extended out of the housing for connection with a light source drive substrate outside the housing. Therefore, the space for placing the light source-mounted substrate inside the housing can favorably be made small, which contributes to size reduction of the lighting device.

In the configuration described above, the light source may be composed of an LED. Generally, an LED is a circuit component that can easily be destroyed by overcurrent or reverse current, but, with this configuration, ESD-induced destruction of the LED can favorably be prevented.

To solve the problems mentioned above, a display device of the present invention includes the lighting device described above, and a display panel that uses the light from the lighting device for display purposes.

### Advantageous Effect of the Invention

According to the present invention, a favorable ESD countermeasure can be provided in a confined space inside a housing to protect a lighting device and light sources from ESD.

### BRIEF DESCRIPTION OF THE DRAWINGS

FIG. is an illustrative cross-sectional view schematically showing a cross-sectional configuration along a long-side direction of a liquid crystal display device according to a first embodiment;

FIG. 2 is a plan view of a backlight device seen from the front side;

FIG. 3 is a plan view of an LED-mounted substrate seen from a light source-mounted surface side;

FIG. 4 is a plan view of the LED-mounted substrate seen from a non-light-source-mounted surface side;

FIG. 5 is a perspective view showing one form of arrangement of the LED-mounted substrate in a housing;

FIG. 6 is a cross-sectional view (cut along the line VI-VI in FIG. 5) illustrating a side plate and the LED-mounted substrate;

FIG. 7 is an illustrative diagram for explaining the effects of ESD;

FIG. 8 is a plan view of an LED-mounted substrate according to a second embodiment seen from a non-light-source-mounted surface side;

FIG. 9 is a perspective view showing one form of arrangement of the LED-mounted substrate in a housing;

FIG. 10 is a cross-sectional view (cut along the line X-X in FIG. 9) illustrating a protruded portion and the LED-mounted substrate;

FIG. 11 is a perspective view showing one form of arrangement of an LED-mounted substrate in a housing according to a third embodiment;

FIG. 12 is a lateral cross-sectional view (cut along the line XII-XII in FIG. 11) illustrating a cantilever portion and the LED-mounted substrate;

FIG. 13 is a longitudinal cross-sectional view (cut along the line XIII-XIII in FIG. 11) illustrating the cantilever portion and the LED-mounted substrate;

FIG. 14 is an illustrative cross-sectional view schematically showing a cross-sectional configuration along a long-side direction of a liquid crystal display device according to a fourth embodiment; and

FIG. 15 is a plan view of a backlight device seen from the front side.

### BEST MODE FOR CARRYING OUT THE INVENTION

### First Embodiment

A first embodiment will be described with reference to the drawings. In this embodiment, a liquid crystal display device 10 will be illustrated. Some of the drawings show X axis, Y axis, and Z axis, which are each drawn to represent respective directions indicated in respective drawings. With respect to the up and down direction, the upper side of FIG. 1 shall be the front side, and the lower side of the figure shall be the back side.

The liquid crystal display device 10 is rectangular as a whole. As shown in FIG. 1, the device includes a liquid crystal panel (display panel) 11 having a display surface 11A that can display images, a bezel 14 having a frame shape surrounding the display surface 11A of the liquid crystal panel 11, and a backlight device (lighting device) 20 that is an external light source disposed on the back side of the liquid crystal panel 11 and projecting light to the liquid crystal panel 11 for display purposes. The liquid crystal display device 10 according to this embodiment is to be used for electronic equipment (not shown) such as various industrial appliances and amusement equipment.

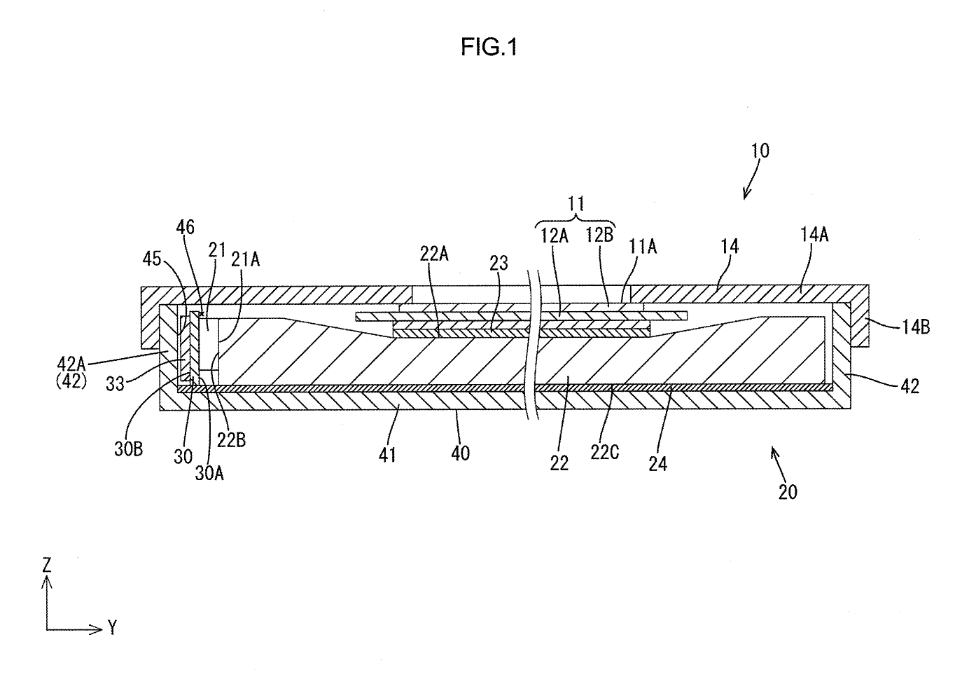

The liquid crystal panel 11 includes, as shown in FIG. 1, a pair of transparent (light transmissive) glass substrates 12A and 12B, and a liquid crystal layer (not shown) interposed between both substrates 12A and 12B and containing liquid crystal molecules, which are a substance whose optical characteristics change when an electric field is applied. Both substrates 12A and 12B are bonded together with a sealant (not shown), with a gap defined by the thickness of the liquid crystal layer being maintained. Of the substrates 12A and 12B, the one on the back side (rear side) is the array substrate 12A, and the one on the surface side (front side) is the CF substrate 12B. The CF substrate 12A has a smaller dimension in the Y-axis direction than the array substrate 12B as shown in FIG. 1 and FIG. 2. The array substrate 12B is provided with switching elements (e.g., TFTs) connected to source lines and gate lines intersecting each other at right angles, pixel electrodes connected to the switching elements, orientation films, and so on. The CF substrate 12B is provided with color filters having color units such as R (red), G (green), and B (blue) arrayed in a predetermined pattern, counter electrodes, orientation films, and so on. A portion of the array substrate 12B that does not overlap with the CF substrate 12A is exposed to the outside both on the front and back, to secure a region for mounting a driver (not shown) and a panel-side flexible substrate (not shown). Therefore, image data and various control signals necessary for displaying images are supplied from a drive circuit substrate (not shown) to the source lines, gate lines, counter electrodes, and so on. A polarizing plate (not shown) is disposed on the outer side of both substrates 12A and 12B.

The bezel 14 is in the shape of a rectangular frame extending along the outer peripheral edges of the liquid crystal panel 11 and made of a metal material such as aluminum. The bezel 14 includes a pressing portion 14A that presses all around a frame-like non-display region along the outer peripheral edges of the liquid crystal panel 11 from the front side, and peripheral walls 14B that extend downward from the outer peripheral edges of the pressing portion 14A and surround all around the backlight device 20. The bezel 14 is assembled into a housing 40 that forms the backlight device 20 such that the liquid crystal panel 11 is sandwiched between the backlight device 20 and the bezel 14.

Next, the backlight device 20 will he described. The backlight device 20 at least includes, as shown in FIG. 1 and FIG. 2, LEDs (Light Emitting Diodes, one example of light source) 21, an LED-mounted substrate (light source-mounted substrate) 30 on which the LEDs 21 are mounted, a metal housing 40 accommodating the LEDs 21, and an LED drive substrate (light source drive substrate) 26 that is disposed outside the housing 40 and drives the LEDs 21. The backlight device 20 further includes a light guide plate 22 that guides light froms the LEDs 21, an optical sheet (optical member) 23 laminated on the front side of the light guide plate 22, and a reflective sheet (reflective member) 24 laminated on the back side of the light guide plate 22. These light guide plate 22, optical sheet 23, and reflective sheet 24, as well as the liquid crystal panel 11 described above, are accommodated inside the housing 40 with the LEDs 21. In FIG. 1, a seciotn of the LED-mounted substrate 30 (extended-out portion 36 to be described later) and the LED drive substrate 26 are not shown. In FIG. 2, the optical sheet 23 is not shown. Below, the components of the backlight device 20 will each be described.

The LED 21 is configured as shown in FIG. 1, in which an LED chip (LED element) that is a semiconductor light emitting element is sealed with a resin material on a substrate portion that is fixedly attached to the LED-mounted substrate 30. The LED chip mounted on the substrate portion has one main light-emitting wavelength. More specifically, the LED chip that emits only one color, blue, is used. The resin material that seals the LED chip, on the other hand, contains a fluorescent substance dispersed therein that emits light of a predetermined color when excited by the blue color from the LED chip so that the LED emits substantially white light as a whole. This LED 21 is the one known as top emission type, which has the light emitting surface 21A on the opposite side from the surface that is mounted to the LED-mounted substrate 30.

A plurality of LEDs 21 described above are mounted on one substrate surface 30A of the LED-mounted substrate 30 as shown in FIG. 2. The LED-mounted substrate 30 is interposed between the mounted LEDs 21 and the LED drive substrate 26 disposed outside the housing 40 and serves the function of electrically connecting them. The configuration of each portion of the LED-mounted substrate 30, and the arrangement and design of the LED-mounted substrate 30 will be described later.

The optical sheet 23 is in the shape of a horizontally long rectangle in plan view as with the liquid crystal panel 11 and housing 40 as shown in FIG. 1. The optical sheet 23 is placed on the front side of the light guide plate 22 (light emitting side) . With the optical sheet 23 being interposed between the liquid crystal panel 11 and the light guide plate 22, predetermined optical effects are given to the light emitted from the light guide plate 22 as it passes through the optical sheet 23 and exits toward the liquid crystal panel 11. The optical sheet 23 is made of a plurality of sheet-like members stacked upon one another. Specific examples of optical sheets 23 include diffusive sheets, lens sheets, reflective polarizing sheets, and so on, and a suitable type selected from these can be used.

The light guide plate 22 is made of a synthetic resin material (e.g., acrylic resin such as PMMA or polycarbonate) that has a sufficiently higher refractive index than that of air and is substantially transparent (highly transmissive) . The light guide plate 22 is in the shape of a horizontally long rectangle in plan view as with the liquid crystal panel 11 and in the form of a plate with a larger thickness than that of the optical sheet 23 as shown in FIG. 1 and FIG. 2. The short-side direction and long-side direction of the plate surface respectively correspond to the X-axis direction and Y-axis direction, and the plate thickness direction orthogonal to the plate surface corresponds to the Z-axis direction. The surface of the light guide plate 22 facing the front side (opposite the liquid crystal panel 11 and optical sheet 23) is the light emitting surface 22A that emits light from inside toward the optical sheet 23 and liquid crystal panel 11. Of the outer circumferential end faces of the light guide plate 22, the one end face extending along the Z-axis direction and Y-axis direction is arranged opposite each of the LEDs 21, i.e., it is the light incident surface 22B which the light from each LED 21 enters. The light guide plate 22 has the function of introducing the light from each LED 21 through the light incident surface 22B and guiding the light up toward the optical sheet 23 side (front side or light emitting side) as the light propagates therein and out from the plate surface. Namely, the backlight device 20 according to this embodiment is the one known as edge light (side light) type.

The reflective sheet 24 is disposed on the back side of the light guide plate 22 as shown in FIG. 1, in such a way as to cover the opposite plate surface 22C opposite from the light emitting surface 22A. This reflective sheet 24 has a white, highly reflective synthetic resin sheet member on its surface to be able to effectively direct the light propagating through the light guide plate 22 up toward the front side (light emitting surface 22A) . The reflective sheet 29 has a rectangular outer shape slightly larger than the light guide plate 22 and is disposed such that, while its central portion is sandwiched between the light guide plate 22 and the bottom plate 41 of the housing 40, its outer peripheral edges protrude out more than the outer circumferential end faces of the light guide plate 22.

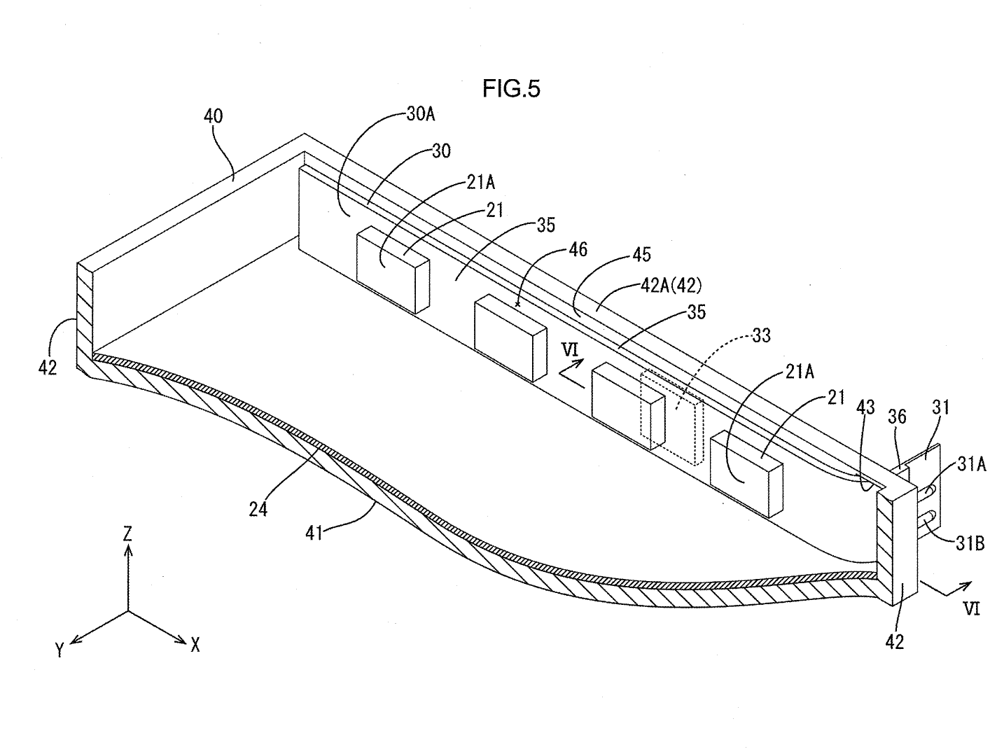

The housing 40 is made from a sheet of metal such as aluminum or electrogalvanized steel (SECC), for example, and conductive. This housing 40 is grounded by a known technique as required. The housing 40 is formed from a metal sheet in a substantially box-like shape and includes the bottom plate 41 that is rectangular in plan view as with the liquid crystal panel 11, and side plates 42 each extending upright toward the front side from the outer end of each of the sides (pair of long sides and pair of short sides) of the bottom plate 41, as shown in FIG. 1 and FIG. 5. The long-side direction and short-side direction of the housing 40 (bottom plate 41) correspond to the Y-axis direction and X-axis direction, respectively. The bottom plate 41 is disposed such that its plate surface is parallel to the plate surfaces of the liquid crystal panel 11, light guide plate 22, and optical sheet 23. The side plates 42 are in the form of a rectangular frame as a whole and disposed in such a way as to surround the outer circumferential end faces of the light guide plate 22. Of the side plates 42 forming the four sides, one side plate 42A has the LED-mounted substrate 30 disposed on its inner face 45. The side plate 42A is disposed along the short-side direction (X-axis direction) and opposite the light incident surface 22B of the light guide plate 22. In other words, inside the housing 40 is formed an LED-mounted substrate placement portion 46, which is a space for placing the LED-mounted substrate 30, between the side plate 42A and the light incident surface 22B of the light guide plate 22 facing the former. The size of the LED-mounted substrate placement portion 46 is set such that, while the length along the X-axis direction is equal to that of the side plate 42A, the length along the Y-axis direction equals to the sum of the thickness of the LEDs 21 and the thickness of the LED-mounted substrate 30, plus a slight clearance. A through hole 43 is formed to extend through the side plate 42A at one end in the longitudinal direction (X-axis direction) for allowing the LED-mounted substrate 30 to extend out of the housing 40.

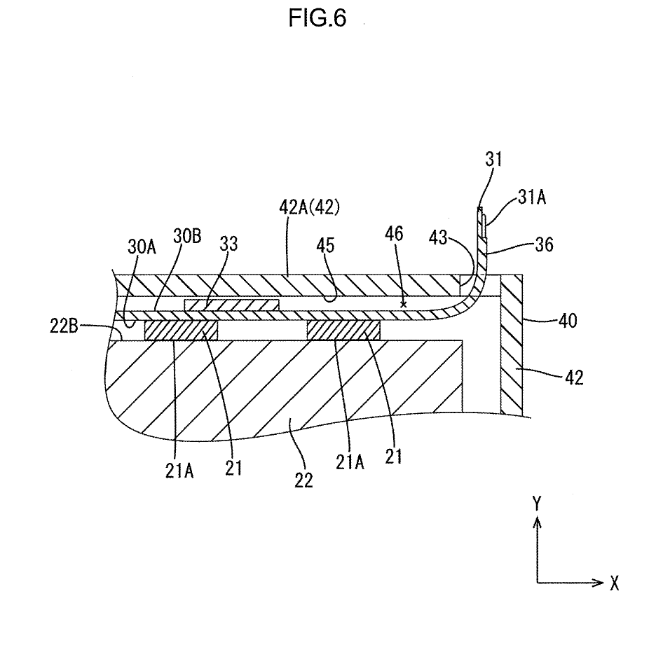

The through hole 43 is slightly larger than the cross-sectional shape in the width direction of the LED-mounted substrate 30 as shown in FIG. 5 and FIG. 6. The hole edge is smoothed to remove burrs and chamfered. The through hole 93 being thus formed allows the LED-mounted substrate 30 to be passed through without any damage. A portion of the LED-mounted substrate 30 that passes through the through hole 43 and is extended out of the housing 40 (connector portion 31 of the extended-out portion 36 to be described later) is connected to the LED drive substrate 26.

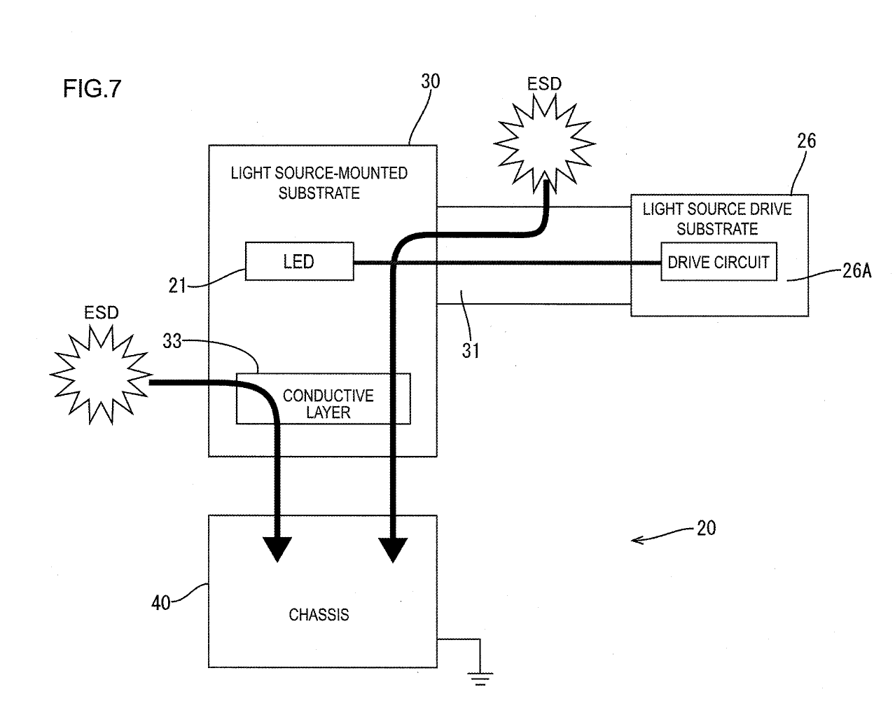

A drive circuit 26A for driving the LEDs 21 is provided to the LED drive substrate 26. Various circuit components (not shown) that form the drive circuit 26A are mounted on the LED drive circuit substrate (see FIG. 7) . The LED drive substrate 26 includes an LED-mounted substrate connecting portion 26B that connects the drive circuit 26A and the LED-mounted substrate 30, as shown in FIG. 2. The LED drive substrate 26 is connected to a power supply circuit substrate (not shown) that is a power supply source of this liquid crystal display device 10, and configured to supply the power from the power supply circuit substrate to the LEDs 21 via the LED-mounted substrate 30 connected to the LED-mounted substrate connecting portion 26B. While one configuration is shown in this embodiment in which the connector portion 31 of the LED-mounted substrate 30 is directly connected to the LED-mounted substrate connecting portion 26B, the form of connection between the LED drive substrate 26 and the LED-mounted substrate 30 is not limited to this. For example, the connector portion of the LED-mounted substrate 30 may be indirectly connected to the LED-mounted substrate connecting portion 26B via another member having a relay wire or the like. While one configuration is shown in this embodiment in which the LED drive substrate 26 is disposed on one side of the housing 40, i.e., adjacent to not the bottom plate 41 but the side plate 42, the arrangement and configuration of the LED drive substrate 26 can be designed in other manners as required according to the design of the liquid crystal display device 10 and the electronic equipment to which the device is mounted.

Various components of the LED-mounted substrate 30 are described next. The LED-mounted substrate 30 is the one known as a flexible substrate (FPC), and composed of a film-like base member (support layer) made of an insulating and flexible synthetic resin material (e.g., polyimide resin and the like), with a conductive layer and the like formed thereon. A flexible substrate adopted as the LED-mounted substrate 30 is, as compared to a hard substrate, small in thickness, and allows portion of it to be readily bent to extend the connector portion 31 out of the housing 40. The LED-mounted substrate itself therefore takes up a small volume inside the housing 40, and does not require a space inside the housing 40 for accommodating the connector portion and other portions to which the connector portion is connected. This in turn enables reduction of the LED-mounted substrate placement portion 46 that is the space allotted to the LED-mounted substrate 30 inside the housing 40, which contributes to size reduction of the backlight device 20.

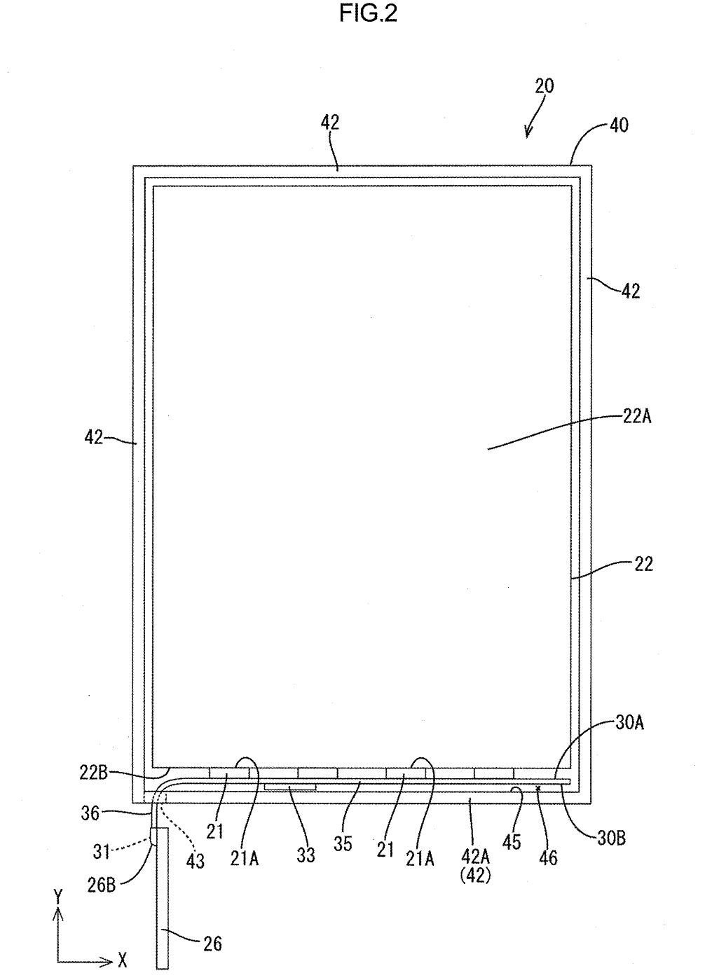

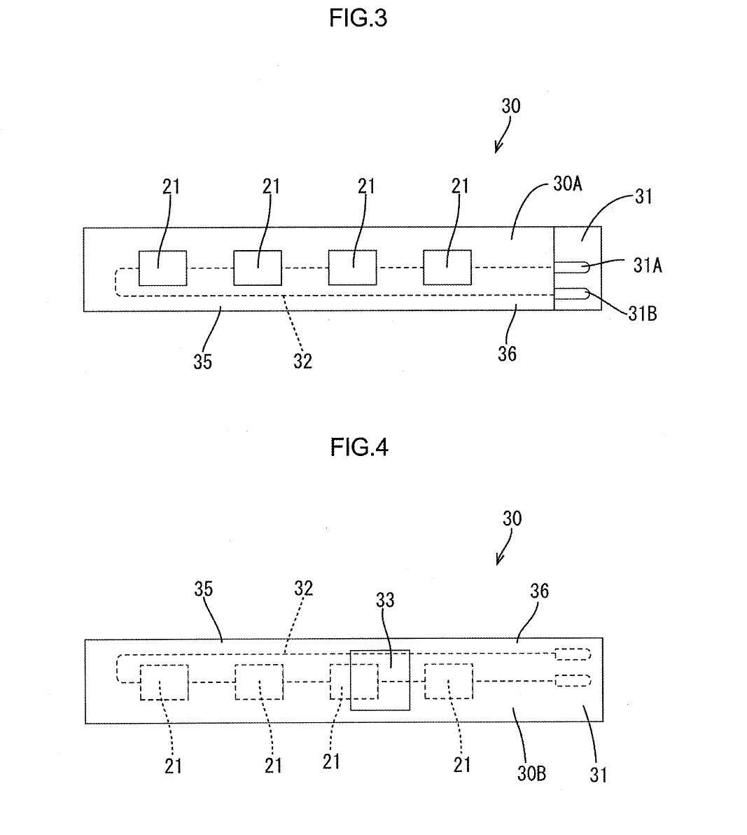

The LED-mounted substrate 30 is in the form of a strip (band-like and elongated) as a whole as shown in FIG. 3 and FIG. 4. One substrate surface 30A is the LED-mounted surface 30A on which the LEDs 21 are mounted, while the other substrate surface 30B is the non-LED-mounted surface 30B where no LED 21 is mounted. The LED-mounted substrate 30 includes an elongated main body 35 where the LEDs 21 are mounted, and the extended-out portion 36 continuous with one end of the main body 35 in the longitudinal direction and extended out along the longitudinal direction. A plurality of LEDs 21 are mounted to the main body 35, spaced apart along the longitudinal direction (X-axis direction). More specifically, the LEDs 21 are fixedly mounted on the LED-mounted surface 30A of the main body 35 by soldering (not shown), whereby electrical connection is established between the LEDs 21 and the LED-mounted substrate 30 (in particular, its wiring pattern 32). The connector portion 31 is formed at the distal end of the extended-out side of the extended-out portion 36.

The LED-mounted substrate 30 includes the connector portion 31 connected to the LED drive substrate 26, the wiring pattern 32 that connects the connector portion 31 and the LEDs 21, and a conductive layer 33 that is conductive but electrically independent of the wiring pattern 32 at a position overlapping the wiring pattern 32. More specifically, the LED-mounted substrate 30 has a configuration known as double-sided mounted FPC in which the wiring pattern 32 is formed on the LED-mounted surface 30A of the base member and the conductive layer 33 is formed on the non-LED-mounted surface 30B of the base member. The connector portion 31 is provided at one end of the LED-mounted substrate 30 in the longitudinal direction.

A pair of connector terminals 31A and 31B that are connected to the anode and cathode terminals of the LEDs 21 respectively via the wiring pattern 32 are provided to the connector portion 31, as shown in FIG. 2. This connector portion 31 is configured to be insertable to the LED-mounted substrate connecting portion 26B of the LED drive substrate 26. With the connector terminals 31A and 31B being electrically connected to the drive circuit 26A via the LED-mounted substrate connecting portion 26B, power is supplied to each LED 21, and drive of each LED 21 is controlled.

The wiring pattern 32 has the plurality of LEDs 21 connected in series as shown in FIG. 2, and is made of metal foil patterned on the base member, most of which is covered by a cover layer (cover film) (not shown). The cover layer is made of a flexible and insulating synthetic resin (e.g., polyimide resin) film. In other words, the wiring pattern 32 can also be considered as internal wiring formed inside and not exposed on the substrate surface 30A of the LED-mounted substrate 30, in contrast to the conductive layer 33 that is exposed on the substrate surface 30B of the LED-mounted substrate 30. Fart of the wiring pattern 32 that is not covered by the cover layer is the mounting portion (not shown) where anode and cathode terminals of the LEDs 21 are connected by soldering. While the wiring pattern is illustrated simply as a straight line in FIG. 2, the shape and arrangement of the pattern can be designed in any manner.

The conductive layer 33 is made of metal foil formed over a predetermined area as shown in FIG. 3. The conductive layer 33 is not covered by the cover layer (cover film) or the like and exposed on the non-LED-mounted surface 30B. The conductive layer 33 is insulated from the wiring pattern 32 by an insulating base member interposed between itself and the wiring pattern 32. The conductive layer 33 in this embodiment is formed as a solid square near the center of the LED-mounted substrate 30 in the longitudinal direction. The shape, size, and arrangement of the conductive layer 33 can be designed in any other manners as required.

The arrangement and configuration of the LED-mounted substrate 30 are described next. The main body 35 of the LED-mounted substrate 30 is disposed in the LED-mounted substrate placement portion 46 inside the housing 40. This main body 35 is arranged in such a way as to extend along the inner face 45 of the side plate 42A (along the Y-axis direction and Z-axis direction). The LED-mounted surface 30A of the LED-mounted substrate 30 faces the light incident surface 22B of the light guide plate 22, while the non-LED-mounted surface 30B faces the sideplate 42A of the housing 40. Between the LED-mounted surface 30A and the light incident surface 22B of the light guide plate 22 are the LEDs 21 mounted on the LED-mounted substrate 30, with their light emitting surfaces 21A in close proximity to or in contact with the light incident surface 22B.

The non-LED-mounted surface 30B is arranged opposite the inner face 45 of the side plate 42A of the housing 40. The conductive layer 33 is exposed on the non-LED-mounted surface 30B, so that the conductive layer 33 is in close proximity to or in contact with the inner face 45 of the side plate 42A. FIG. 6 illustrates one form in which there is a slight clearance between the conductive layer 33 and the inner face 45 of the housing 40. This clearance is set to a size that can absorb thermal expansion or the like of the LED-mounted substrate 30 and allow electrical conduction between the conductive layer 33 and the housing 40 when a large current flows through the conductive layer 33.

The extended-out portion 36 of the LED-mounted substrate 30 passes through the through hole 43 of the side plate 42 and is extended out of the housing 40. More specifically, the LED-mounted substrate 30 is bent between the main body 35 and the extended-out portion 36, such that the extended-out portion 36 extends toward the LED drive substrate 26 disposed outside the housing 40. While one configuration is shown in this embodiment in which the LED drive substrate 26 is disposed adjacent to the housing 40 and the LED-mounted substrate 30 is extended out straight toward the LED drive substrate 26, the LED-mounted substrate 30 can be extended out in other manners as required according to the design of the liquid crystal display device 10 and the electronic equipment to which the device is mounted. Since the LED-mounted substrate 30 is flexible, its shape can be changed as required, which allows a wide variation of designs of the electronic equipment.

The effects of ESD in this embodiment will now be explained with reference to FIG. 7.

ESD transient current selectively flows through a low impedance location. In the backlight device 20 of this embodiment, the conductive layer 33 of the LED-mounted substrate 30 is exposed on the substrate surface 30B of the LED-mounted substrate 30, and disposed in close proximity to or in contact with the housing 40, which is a large conductor. The impedance is lower in the conductive layer 33 than in other portions of the LED-mounted substrate 30 or LED drive substrate 26 (wiring pattern 32, drive circuit 26A, and so on) . Namely, the current caused by ESD that has occurred near the LED-mounted substrate 30 or LED drive substrate 26 flows more easily to the conductive layer 33 than to the wiring pattern 32 or drive circuit 26A in the backlight device 20. As a result, in this embodiment, even when ESD occurs, the current caused by ESD can be released via the conductive layer 33 to the housing 40 that is grounded, and thus the amount of current that flows through the circuit components such as LEDs 21 and drive circuit 26A is reduced as compared to backlight devices without the conductive layer 33.

The effects of this embodiment will be described next. As described above, the backlight device 20 according to this embodiment includes LEDs 21, a metal housing 40 that accommodates the LEDs 21, an LED drive substrate 26 that is disposed outside the housing 40 and drives the LEDs 21, and an LED-mounted substrate 30 on which the LEDs 21 are mounted. The LED-mounted substrate 30 includes a connector portion 31 disposed outside the housing 40 and connected to the LED drive substrate 26, a wiring pattern 32 that connects the connector portion 31 and the LEDs 21, and a conductive layer 33 that is exposed on a substrate surface 30B facing the housing 40 at a position overlapping the wiring pattern 32 and is conductive but electrically independent of the wiring pattern 32. The display device of this embodiment includes the backlight device 20 described above, and a liquid crystal panel 11 that uses light from the backlight device 20 for display purposes.

For the LED-mounted substrate 30 disposed in the LED-mounted substrate placement portion 46 that is a confined space inside the housing 40, this embodiment adopts a configuration in which the housing 40 and the conductive layer 33 exposed on the substrate surface 30B opposite the housing are conductive to each other, by utilizing the structure in which the LED-mounted substrate 30 and housing 40 are disposed in close proximity to each other. This conductive layer 33 is provided as a laminar member at a position overlapping the wiring pattern 32 on the LED-mounted substrate 30 so that it can be formed inside the housing 40 without significantly extending the LED-mounted substrate placement portion 46, as compared to when disposing an additional component separate from the LED-mounted substrate 30 inside the housing 40, or when securing an area for forming the conductive layer 33 in such a manner that the area of the substrate surface 30B of the LED-mounted substrate 30 is increased. Thus, the low-impedance conductive layer 33 can be formed favorably even in a confined space inside the housing 40 to release ESD current to the housing 40 via the conductive layer 33. As a result, ESD-induced malfunctions of the backlight device 20 and destruction of circuit components such as LEDs 21 and drive circuit 26A can be prevented favorably.

In this embodiment, the LED-mounted substrate 30 has the LEDs 21 mounted on one substrate surface 30A and the conductive layer 33 formed on the other substrate surface 30B, and is disposed such that the other substrate surface 30B faces an inner face 45 of the housing 40. This is preferable because when the LED-mounted substrate 30 is accommodated inside the housing 40, the conductive layer 33 can be positioned opposite the housing 40.

In this embodiment, a protruded portion 148 is provided on the inner face 45 of the housing 40, and the LED-mounted substrate 30 has the conductive layer 33 formed at a position facing the protruded portion 148. As compared to the configuration without the protruded portion 148, the distance between the conductive layer 33 and the inner face 45 of the housing 40 can be made smaller, which is preferable for releasing the current from the conductive layer 33 to the housing 40.

In this embodiment, the housing 40 may include a bottom plate 41, a side plate 40A extending upright from a peripheral end of the bottom plate 41, and a through hole 43 extending through the side plate 40A. The LED-mounted substrate 30 may be disposed on the inner side of the side plate 42A, and the connector portion 31 may be extended out of the housing 40 through the through hole 43. With this configuration, the space for placing the LED-mounted substrate 30 inside the housing 40 can favorably be made small, which contributes to size reduction of the backlight device 20.

In this embodiment, the LED-mounted substrate 30 is a flexible substrate having flexibility. A flexible substrate generally has a small thickness and can readily be bent in part to be extended out of the housing 40 for connection with the LED drive substrate 26 outside the housing 40. Therefore, the LED-mounted substrate placement portion 46, which is the space for installing the LED-mounted substrate 30 inside the housing 40, can favorably be made small, which contributes to size reduction of the backlight device 20.

In this embodiment, light sources composed of LEDs 21 are shown as one example. Generally, an LED is a circuit component that can easily be destroyed by overcurrent or reverse current, but, with this configuration, ESD-induced destruction of LEDs 21 can favorably be prevented.

### Second Embodiment

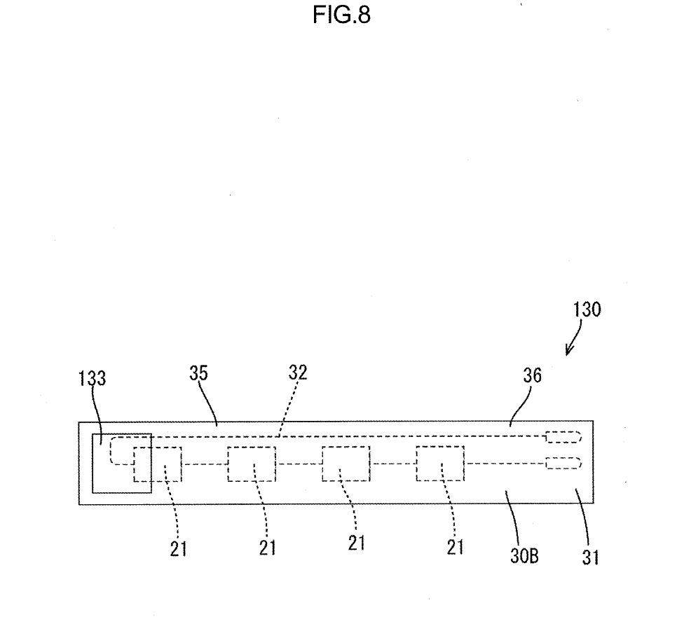

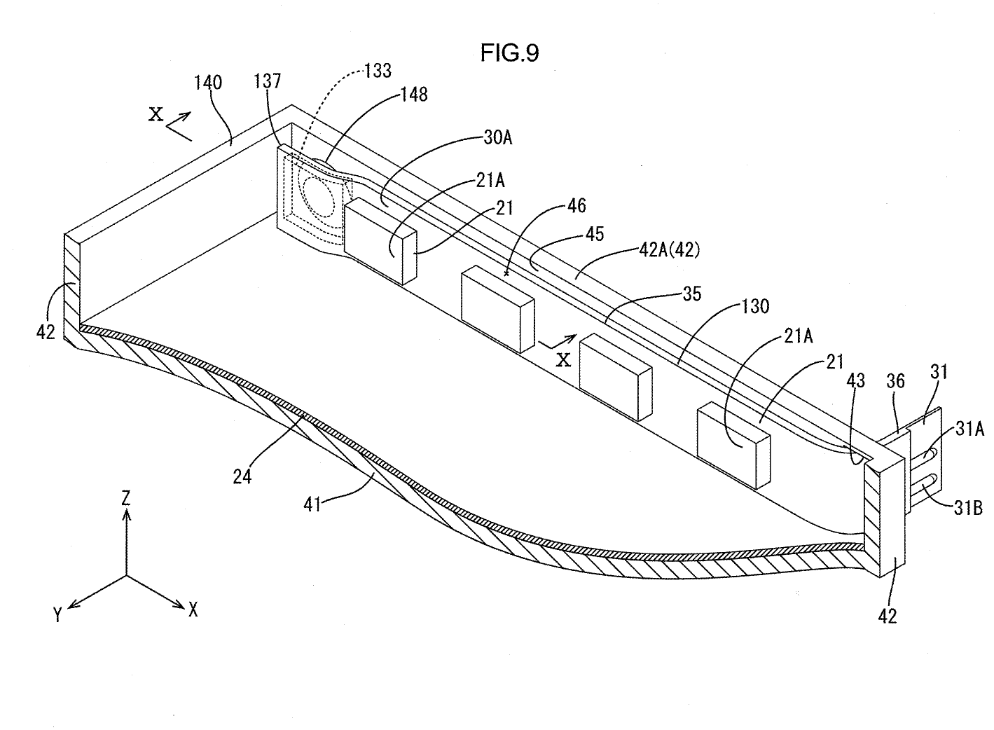

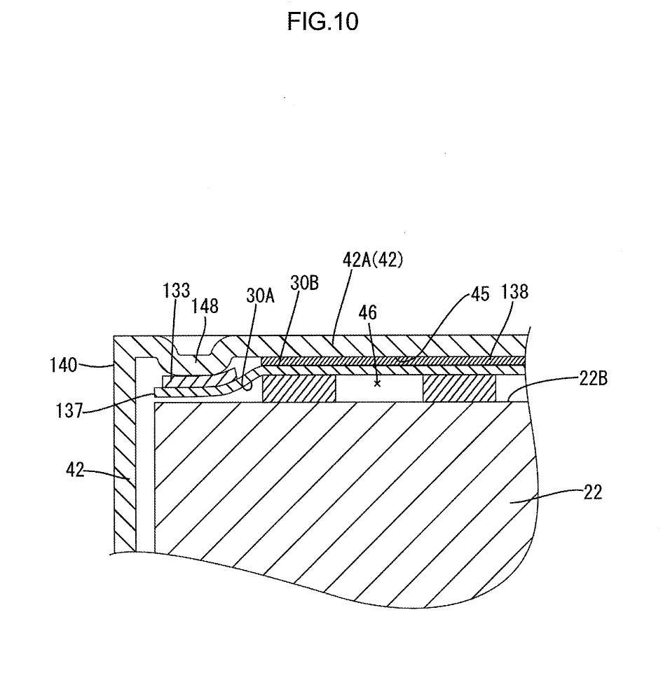

Next, a second embodiment of the present invention will be described with reference to FIG. 8 to FIG. 10. A backlight device 120 will be described in this embodiment, which differs from that of the first embodiment in that a protruded portion 148 is formed on an inner face 45 of a housing 140. The basic configuration of the backlight device 120 of this embodiment is similar to that of the first embodiment. Therefore, the elements that are identical to those of the first embodiment are given the same reference numerals as the first embodiment, and will not be described in detail.

The protruded portion 148 is formed at one end on the opposite side from the end where a through hole 43 is formed in the longitudinal direction (X-axis direction) of a side plate 42. The protruded portion 148 is formed integrally with the side plate 42 by a drawing process performed to a side plate 42A. Therefore, the side plate 42 and an LED-mounted substrate 130 are directly conductive, unlike the case where electrical conduction is achieved between the housing 140 and the LED-mounted substrate 130 using a fastening member such as a screw that is separate from the housing 140. A protruded portion 148 is formed in an area of the LED-mounted substrate 130 not overlapping the area where the LEDs 21 are mounted, and protruded to a height not exceeding the height of the LEDs 21 from the LED-mounted surface 30A.

The LED-mounted substrate 130 has a conductive layer 133 positioned opposite the protruded portion 148. More specifically, the LED-mounted substrate 130 has a conductive layer 133 at one peripheral end 137 opposite from the connector portion 31. The end 137 of the LED-mounted substrate 130 is resiliently deformed in such a way as to ride onto the protruded portion 148, so that the conductive layer 133 in contact with the protruded portion 148 is biased toward the protruded portion 148. Part of the LED-mounted substrate 130 adjacent to the conductive layer 133 is fixed to the inner face 45 of the side plate 42A via a double-sided adhesive tape 138.

In this embodiment in which the housing 140 includes the protruded portion 148, the distance between the conductive layer 133 and the inner face 45 of the housing 140 can be made small as compared to the configuration without the protruded portion 148, so that electrical current can be released from the conductive layer 133 to the housing 140 favorably.

In this embodiment, the LED-mounted substrate 130 is a flexible substrate having flexibility, and has the conductive layer 133 formed at its peripheral end 137. The peripheral end 137 is resiliently deformed in such a way as to ride onto the protruded portion 148 so that the conductive layer 133 in contact with the protruded portion 148 is biased toward the protruded portion. Thus, the conductive layer 133 and protruded portion 148 can favorably be contacted to each other, which is favorable for releasing the electric current from the conductive layer 133 to the housing 140.

In this embodiment, the LED-mounted substrate 130 is fixed to the housing 140 at a position in close proximity to the conductive layer 133. The conductive layer 133 is thus prevented from displacing away from the housing 140, which allows favorable release of electric current from the conductive layer 133 to the housing 140.

### Third Embodiment

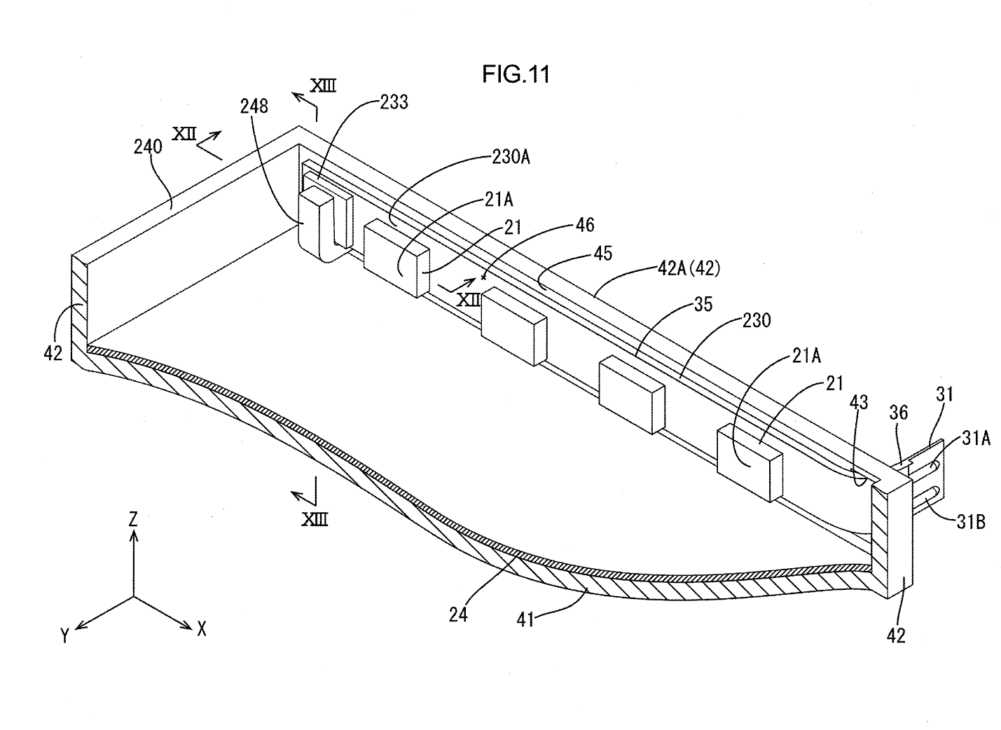

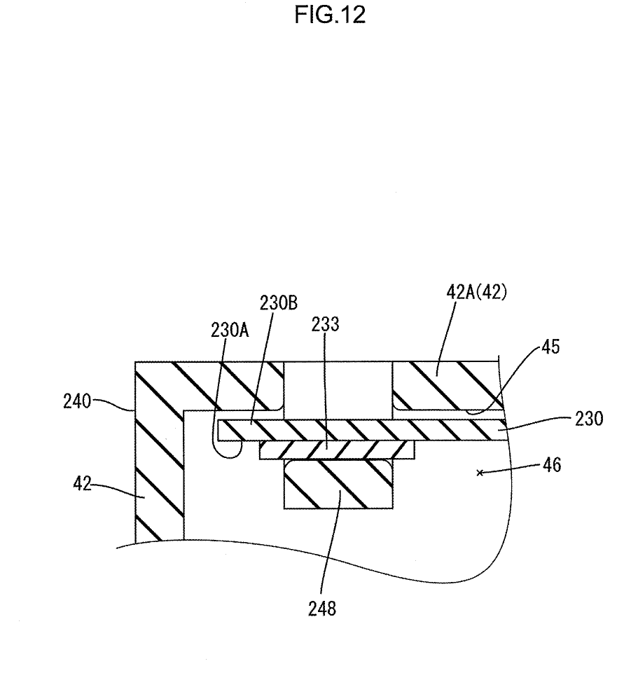

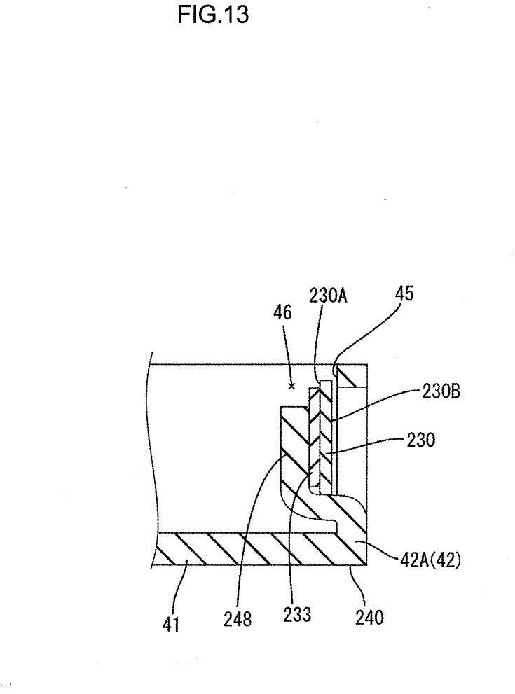

Next, a third embodiment of the present invention will be described with reference to FIG. 11 to FIG. 13. A backlight device 220 will be described in this embodiment, which differs from that of the first embodiment in that a housing 240 includes a cantilever portion 248. The basic configuration of the backlight device 220 of this embodiment is similar to that of the first embodiment. Therefore, the elements that are identical to those of the first embodiment are given the same reference numerals as the first embodiment, and will not be described in detail.

The housing 240 includes a sideplate 42, on the inner side of which an LED-mounted substrate 230 is disposed, and the cantilever portion 248 that is cut away from the side plate 42 in a cantilevered manner for holding an LED-mounted substrate 230 between itself and the side plate 42. In this embodiment, the cantilever portion 248 is formed by making a cut in U-shape in the side plate 42. The cut end faces of the cantilever portion 248 and side plate 42 are smoothed to remove burrs and chamfered. The cantilever portion 248 and side plate 42 being thus formed allow the LED-mounted substrate 230 to be sandwiched without any damage.

The cantilever portion 248 is bent in L-shape at its fixed end so that there is a gap between itself and the side plate for accommodating the LED-mounted substrate 230. The cantilever portion 248 is arranged not to overlap the area where LEDs 21 are mounted on the LED-mounted substrate 230. This embodiment shows one example of the cantilever portion 248 that is located at one end on the opposite side in the longitudinal direction (X-axis direction) of the side plate 42 from the end where the through hole 43 is formed, further closer to the end than the LED 21 positioned at one end in the direction in which the LEDs 21 are aligned at intervals. The arrangement of the cantilever portion 248 is not limited to this, and the cantilever portion may be located between the LEDs 21.

The LED-mounted substrate 230 has a conductive layer 233 positioned opposite the cantilever portion 248. More specifically, in this embodiment, the conductive layer 233 is formed on the LED-mounted surface 230A of the LED-mounted substrate 230, in contrast to the first embodiment described above in which the conductive layer 233 is formed on the non-LED-mounted surface 230B of the LED-mounted substrate 230. The conductive layer 233 is formed in such a way as to overlap the wiring pattern 32 with a cover layer interposed therebetween.

In this embodiment, since the LED-mounted substrate 230 is sandwiched between the cantilever portion 248 and the side plate 42, the conductive layer 233 can readily be contacted to the cantilever portion 248, which allows favorable release of electric current from the conductive layer 233 to the housing 240. Moreover, the cantilever portion 248, which is an element for making the conductive layer 233 and housing 240 conductive to each other, can be used to attach the LED-mounted substrate 230 to the housing 240, so that other components such as a double-sided adhesive tape for attaching the LED-mounted substrate 230 to the housing 240 can be eliminated.

### Forth Embodiment

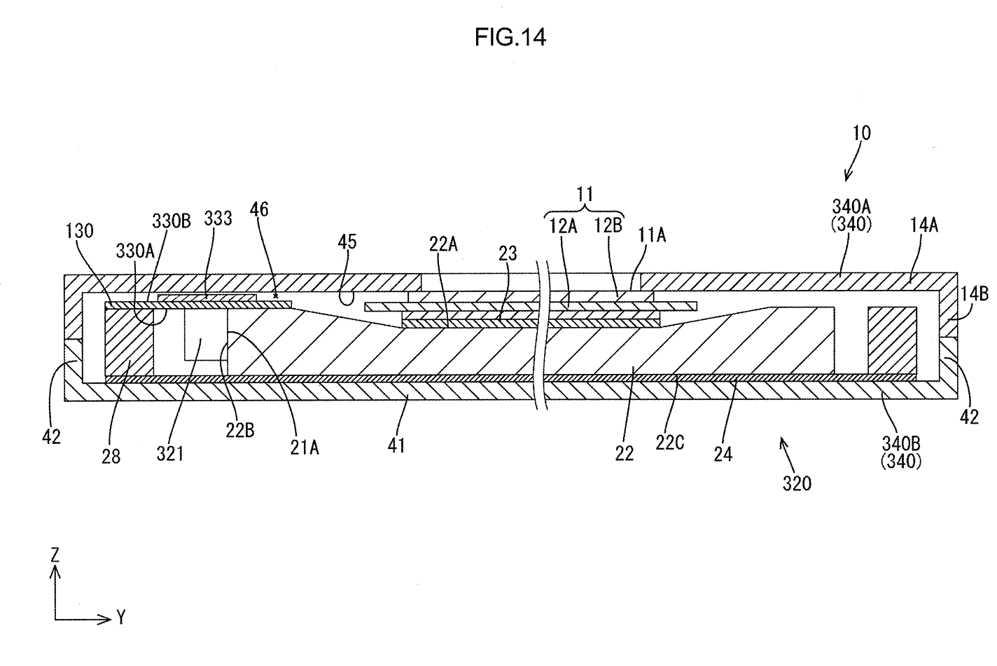

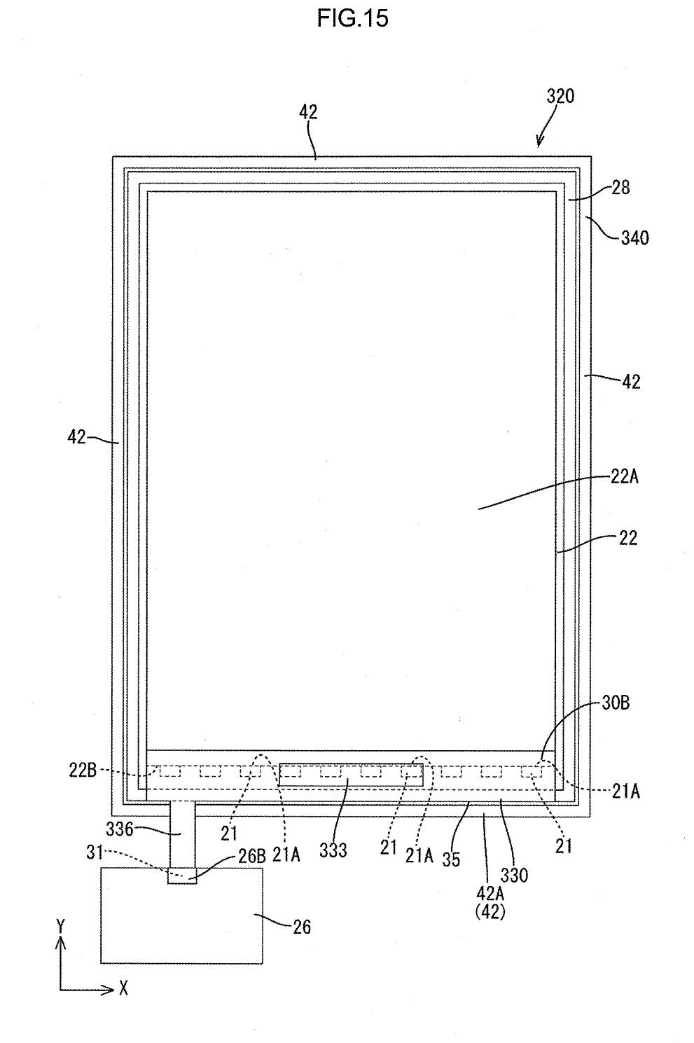

Next, a fourth embodiment of the present invention will be described with reference to FIG. 14 and FIG. 15. A backlight device 320 will be described in this embodiment, which differs from that of the first embodiment in the arrangement of an LED-mounted substrate 330. The basic configuration of the backlight device 320 of this embodiment is similar to that of the first embodiment. Therefore, the elements that are identical to those of the first embodiment are given the same reference numerals as the first embodiment, and will not be described in detail.

The backlight device 320 includes a synthetic resin frame 28 in the form of a frame surrounding a light guide plate 22 inside a housing 340 (back side housing portion 340E) in addition to the components described in the first embodiment. LEDs 321 equipped in the backlight device 320 are the ones known as side emission type, i.e., they each have a light emitting surface 21 on one side relative to the front side (or back side), on which they are mounted to the LED-mounted substrate 330.

The housing 340 is made up of a front side housing portion 340A and a hack side housing portion 340B paired front and back as shown in FIG. 14. The front side housing portion 340A and back side housing portion 340B are assembled such that they are conductive to each other. The front side housing portion 340A can be considered as the component corresponding to the bezel 14 in the first embodiment, and the back side housing portion 340B as the component corresponding to the housing 340. The front side housing portion 340A and back side housing portion 340B are configured similarly to the bezel 14 and housing 340 respectively except for the differences to be described below and therefore will not be described in detail. Inside the housing 340 is formed an LED-mounted substrate placement portion 46, which is a space for placing the LED-mounted substrate 330, between the front side housing portion 340A (pressing portion 14A) and one end of the light guide plate 22 on the light incident surface 22B side and the frame 28, opposite the front side housing portion.

As shown in FIG. 15, the LED-mounted substrate 330 includes an elongated main body 35 where the LEDs 321 are mounted, and a strip-like extended-out portion 336 extended out from the main body 35 in a direction orthogonal to the longitudinal direction of the main body 35. The main body 35 of the LED-mounted substrate 330 is disposed in the LED-mounted substrate placement portion 46 inside the housing 390. The main body 35 is arranged in such a way as to extend along the inner face 45 of the pressing portion 14A of the front side housing portion 340A (along the X-axis direction and 1-axis direction) . The LED-mounted surface 330A of the LED-mounted substrate 330 faces the back side, while the non-LED-mounted surface 330B faces the pressing portion 14A of the front side housing portion 340A. Part of this LED-mounted substrate 330 overlapping the light guide plate 22 is fixed to the light guide plate 22 with a double-sided adhesive tape or the like, and the portion that overlaps the frame 28 is supported by the frame 28. Between the frame 28 and the light incident surface 22B of the light guide plate 22 are the LEDs 321 disposed with their light emitting surfaces 21A in close proximity to or in contact with the light incident surface 22B.

The non-LED-mounted surface 330B is arranged opposite the inner face 45 of the pressing portion 14A of the front side housing portion 340A. The conductive layer 333 is exposed on the non-LED-mounted surface 330B, so that the conductive layer 333 is in close proximity to or in contact with the inner face 45 of the pressing portion 14A. FIG. 14 illustrates one form in which there is a slight clearance between the conductive layer 333 and the inner face 45 of the housing 340. This clearance is set to a size that can absorb thermal expansion or the like of the LED-mounted substrate 330 and allow electrical conduction between the conductive layer 333 and the housing 340 when a large current flows through the conductive layer 333.

The extended-out portion 336 of the LED-mounted substrate 330 passes through a through hole (not shown) of the housing 340 and is extended out of the housing 340. While one configuration is schematically shown in this embodiment in which the LED drive substrate 26 is disposed adjacent to the housing 340 and the LED-mounted substrate 330 is extended out straight toward the LED drive substrate 26, the LED-mounted substrate 330 can be extended out in other manners as required according to the design of the liquid crystal display device 10 and the electronic equipment to which the device is mounted. It can be said that the LED-mounted substrate 330 allows a wide range of designs since it has flexibility and its shape can be changed as required.

### Other Embodiments

The present invention is not limited to the embodiments illustrated by the description given above and the drawings. The following embodiments, for example, are also included in the technical scope of the present invention.

(1) While a double-sided mounted FPC has been illustrated as the LED-mounted substrate in the embodiments described above, the substrate is not limited to this and other known FPCs such as multilayer FPC and the like may be used.

While the light source-mounted substrate has a slight clearance between itself and the side plate in the example shown in the embodiments described above, the light source-mounted substrate need not necessarily have a clearance between itself and the side plate.

(3) In the embodiments described above (except for the second embodiment), the light source-mounted substrate may be fixedly attached to the side plate by a double-sided adhesive tape or the like. In this case, it is preferable to avoid the conductive layer when providing the double-sided adhesive tape on the non-light-source-mounted surface, and it is particularly preferable to dispose the tape at a position adjacent to the conductive layer, so that the conductive layer and housing will be favorably conductive to each other. The second embodiment may also be configured without the double-sided adhesive tape.

(4) The arrangement and number of light sources can be changed as required in other manners than the embodiments described above. Other light sources than LEDs can also be used as the light source.

(5) The shape, arrangement, and number of the light source-mounted substrate can be changed as required in other manners than the embodiments described above.

(6) The structures, arrangements, and numbers of the connector portion and wiring pattern can be changed as required in other manners than the embodiments described above. For example, the connector portion and wiring pattern for connecting the plurality of light sources maybe configured to include a path that connects a group of light sources in series, and another path that connects another group of light sources in series.

(7) The shape, arrangement, number, and material of the conductive layer can be changed as required in other manners than the embodiments described above. For example, the conductive layer may be provided over the entire area of the non-light-source-mounted surface of the light source-mounted substrate (area including the main body and extended-out portion).

(8) The housing shape, forming method, and the form of assembling with other portions can be changed as required in other manners than the embodiments described above.

(9) While one end face of the light guide plate is used as the light incident surface in the embodiments described above, two or more end faces may be used as light incident surfaces. When two or more end faces are used as the light incident surface, light sources and light source-mounted substrates are to be prepared in accordance with the number of light incident surfaces.

(10) While an edge light type backlight device has been shown as one example in the embodiments described above, the invention may be applied to other types of backlight devices as long as the object of the invention is not compromised.

(11) While a liquid crystal display device that uses a liquid crystal panel as the display panel has been shown as one example in the embodiments described above, the invention can be applied to display devices that use other types of display panels.

(12) While TFTs are used as switching elements of the liquid crystal display device in the embodiments described above, the invention can be applied to liquid crystal display devices that use other switching elements than TFTs such as thin film diodes (TFD). The invention is applicable also to liquid crystal display devices with a monotone display other than liquid crystal display devices with a color display.

(13) While the embodiments described above have illustrated a liquid crystal display device that configures portion of electronic equipment (not shown) such as various industrial appliances and amusement equipment, the application is not limited to these. The liquid crystal display device may be used also in other electronic equipment such as portable information terminals including smart phones, tablet terminals, and the like.

### EXPLANATION OF SYMBOLS

10: Liquid crystal display device

11: Display panel

20, 120, 220, 230, 320: Backlight device

21: Light source (LED)

26: LED drive substrate (light source drive substrate)

30, 130, 230, 330: LED-mounted substrate (light source-mounted substrate)

30A, 230A: LED-mounted surface (one substrate surface)

30B, 230B: non-LED-mounted surface (the other substrate surface)

31: Connector portion

32: Wiring pattern

33, 133, 233: Conductive layer

137: One end (peripheral end)

40, 140, 240, 340: Housing

41: Bottom plate

42, 42A: Side plate (plate portion)

43: Through hole

148: Protruded portion

248: Strip portion

1. A lighting device comprising:
a light source;
a housing made of metal and accommodating the light source;
a light source drive substrate disposed outside the housing and configured to drive the light source; and
a light source-mounted substrate on which the light source is mounted, the light source-mounted substrate including a connector portion disposed outside the housing and connected to the light source drive substrate, a wiring pattern connecting the connector portion to the light source, and a conductive layer exposed on a substrate surface facing the housing at a position overlapping the wiring pattern, the conductive layer being conductive but electrically independent of the wiring pattern.

2. The lighting device according to claim 1, wherein
the light source-mounted substrate includes a first substrate surface and a second substrate surface,
the light source is mounted on the first substrate surface,
the conductive layer is formed on the second substrate surface, and
the light source-mounted substrate is disposed such that the second substrate surface faces an inner face of the housing.

3. The lighting device according to claim 2, wherein
the housing includes a protruded portion provided on the inner face, and
the light source-mounted substrate includes the conductive layer formed at a position facing the protruded portion.

4. The lighting device according to claim 3, wherein
the light source-mounted substrate is a flexible substrate having flexibility, and
the light source-mounted substrate includes the conductive layer formed at a peripheral end thereof, the peripheral end being resiliently deformed in such a way as to ride onto the protruded portion so that the conductive layer in contact with the protruded portion is biased toward the protruded portion.

5. The lighting device according to claim 1, wherein the light source-mounted substrate is fixed to the housing at a position in close proximity to the conductive layer.

6. The lighting device according to claim1 , wherein
the housing includes a bottom plate, a side plate extending upright from a peripheral end of the bottom plate, and a through hole extending through the side plate,
the light source-mounted substrate is disposed on an inner side of the side plate, and
the connector portion is extended out of the housing through the through hole.

7. The lighting device according to claim 1, wherein
the housing includes a plate portion and for disposing the light source-mounted substrate on an inner side thereof, and a cantilever portion cut away from the plate portion in a cantilevered manner and sandwiching the light source-mounted substrate between itself and the plate portion, and
the light source-mounted substrate includes the conductive layer formed at a position facing the cantilever portion.

8. The lighting device according to claim 1, wherein the light source-mounted substrate is a flexible substrate having flexibility.

9. The lighting device according to claim 1, wherein the light source is an LED.

10. A display device comprising:
the lighting device according to claim 1; and
a display panel configured to display images using light from the lighting device.
